(19) United States
(12) Patent Application Publication
(10) Pub. No.: US 2006/0019423 A1
(43) Pub. Date: Jan. 26, 2006

(54) Method for manufacturing solid-state image sensor

(75) Inventors: Masakatsu Suzuki, Hirakata-shi (JP); Mitsugu Yoshita, Tonami-shi (JP)

Correspondence Address: HAMRE, SCHUMANN, MUELLER & LARSON P.C., P.O. BOX 2902, MINNEAPOLIS, MN, 55402, US

(73) Assignee: MATSUSHITA ELECTRIC INDUSTRIAL CO., LTD., Kadoma-shi (JP)

(21) Appl. No.: 11/145,675

(22) Filed: Jun. 6, 2005

(30) Foreign Application Priority Data
Jul. 26, 2004 (JP) 2004-217536

(51) Int. Cl. H01L 21/425

(52) U.S. Cl. 438/60; 438/526; 438/527; 438/530

(57) ABSTRACT

In a method for manufacturing a solid-state image sensor including forming a photodetector portion for a photoelectric conversion in a semiconductor substrate, and forming a shift register for transferring a signal charge read out from the photodetector portion, an annealing is carried out after an ion implantation for forming a buried channel region constituting the shift register. It is possible to provide a method for manufacturing a solid-state image sensor that avoids the formation of crystal defects in a shift register and a photodetector portion and achieves an excellent output image quality and a large saturation electric charge.

### BACKGROUND OF THE INVENTION

1. Field of the Invention

The present invention relates to a method for manufacturing a solid-state image sensor. In particular, the present invention relates to a method for manufacturing a solid-state image sensor including steps of forming and processing a buried channel region serving as a transfer channel of a signal charge in a solid-state image sensor and, more specifically, relates to a method for manufacturing a solid-state image sensor that achieves an excellent output image quality and a large saturation electric charge.

2. Description of Related Art

Nowadays, solid-state image sensors using a CCD (a charge coupled device) for reading out a signal charge are in the mainstream. Also, as pixels become finer and finer, there have been a considerable increase in the number of pixels and a significant reduction in the element size.

In general, a solid-state image sensor used in a videotape camera-recorder, a digital still camera or the like has the following structure. A photodetector portion (a PD portion) for obtaining a signal charge by photoelectric conversion and a shift register (a CCD portion) for transferring the signal charge that is read out from the photodetector portion are formed on a silicon substrate. On this silicon substrate, a transfer gate electrode is formed via an insulating film. Further, on the transfer gate electrode, there are an interlayer insulating film, a light-shielding film having an opening above the photodetector portion (a film for shielding a surface side except for the photodetector portion from light) and a surface protection film in this order. Further, a flattening film, a color filter and a microlens are layered in this order, as necessary. The photodetector portions and the shift registers (for example, vertical transfer CCD portions) are arranged two-dimensionally in an alternating manner, and a pair of the photodetector portion and the shift register (for example, the vertical transfer CCD portion) constitutes a single pixel. An electric charge generated by the incidence of light into the photodetector portion is transferred sequentially by driving the transfer gate electrode by applying a predetermined signal thereto, and then outputted as an image signal from an output portion.

The photodetector portion and the shift register are formed by ion implantation into a semiconductor substrate. In the ion implantation for forming the photodetector portion, the kinetic energy of ions to be implanted scatters atoms constituting a crystal, thus generating many point defects such as pairs of vacancy and interstitial atom. When the concentration of the generated point defects such as pairs of vacancy and interstitial atom increases, some of them are bound together to form stable crystal defects. This increases white point defects (a kind of image defects) and dark current, leading to a problem of deteriorating image quality. An increase in the dark current also causes a problem that, even when taking a photograph of a pitch-dark object, the captured image looks gray or even white in some extreme cases.

In order to solve these problems, after the ion implantation for forming the photodetector portion, an annealing or a high-temperature heat treatment also serving other purposes is carried out, thereby removing the generated point defects such as pairs of vacancy and interstitial atom. It also has been suggested that the ion implantation process is divided into plural processes to be conducted at separate times and the annealing is carried out after each time of ion implantation (see JP 10(1998)-135441 A, for example).

On the other hand, in the ion implantation for forming the shift register, point defects such as pairs of vacancy and interstitial atom also are generated. When some of them are bound together to form stable crystal defects, image defects called white vertical lines are generated. However, since an acceleration energy of the ion implantation for forming the shift register generally is lower than that for forming the photodetector portion, fewer point defects such as pairs of vacancy and interstitial atom, which may cause crystal defects, are generated. Accordingly, by adjusting the dose of ion implantation, it has been possible to suppress the generation of image defects, thus eliminating the need for the additional annealing that is different from the subsequent high-temperature heat treatment and removes the point defects such as pairs of vacancy and interstitial atom.

However, as pixels become finer and finer, the pixel area decreases, for example, the surface area corresponding to a single pixel including a pair of the photodetector portion and the shift register becomes 2.8 μm×2.8 μm or smaller, so that a saturation electric charge (a maximum storage electric charge) is reduced. In order to compensate for this reduction, the impurity concentration (the dose of ion implantation) in the photodetector portion and the shift register has been raised. When the impurity concentration increases, more point defects such as pairs of vacancy and interstitial atom are generated at the time of ion implantation, so that the crystal defects formed by the bound and stabilized point defects also increase, leading to an increase in so-called white point defects, white vertical lines and dark current. Consequently, there has been a problem that a sufficient improvement in the image quality is difficult to achieve simply by carrying out the annealing after the ion implantation for forming the photodetector portion as in the solid-state image sensor described in JP 10(1998)-135441 A. Furthermore, even in the case where pixels have not become finer, a similar problem arises with an increase in the impurity concentration (the dose of ion implantation) in the photodetector portion and the shift register when it is necessary to increase the saturation electric charge (the maximum storage electric charge).

### SUMMARY OF THE INVENTION

With the above-described problems in mind, it is an object of the present invention to provide a method for manufacturing a solid-state image sensor that achieves an excellent output image quality and a large saturation electric charge by avoiding the formation of crystal defects in a shift register and a photodetector portion.

In order to solve the above-mentioned problems, a method for manufacturing a solid-state image sensor according to the present invention includes forming a photodetector portion for a photoelectric conversion in a semiconductor substrate, and forming a shift register for transferring a signal charge read out from the photodetector portion, wherein the forming of the shift register includes an annealing after an ion implantation for forming a buried channel region constituting the shift register.

Also, in the above-noted method for manufacturing a solid-state image sensor according to the present invention, it is preferable that the shift register includes an n-type buried channel region and a p-type region located under the buried channel region, the ion implantation for forming the shift register includes a first ion implantation for forming the n-type buried channel region and a second ion implantation for forming the p-type region located under the buried channel region, and the annealing is carried out after the first ion implantation and the second ion implantation.

Further, in the above-noted method for manufacturing a solid-state image sensor according to the present invention, it is preferable that an impurity used for the ion implantation or an impurity used for the first ion implantation is arsenic.

Moreover, in the above-noted method for manufacturing a solid-state image sensor according to the present invention, it is preferable that a temperature of the annealing is set to be equal to or higher than a highest temperature of processing steps thereafter.

Furthermore, in the above-noted method for manufacturing a solid-state image sensor according to the present invention, it is preferable that a temperature of the annealing is 950° C. to 1050° C.

Additionally, in the above-noted method for manufacturing a solid-state image sensor according to the present invention, it is preferable that a period for the annealing is 20 to 60 seconds.

Also, in the above-noted method for manufacturing a solid-state image sensor according to the present invention, it is preferable that a heating rate of the annealing is 10° C./second to 100° C./second.

Further, in the above-noted method for manufacturing a solid-state image sensor according to the present invention, it is preferable that the annealing is carried out in a nitrogen atmosphere.

In addition, the method for manufacturing a solid-state image sensor according to the present invention is preferred when manufacturing a solid-state image sensor in which a surface area corresponding to a single pixel including a pair of the photodetector portion and the shift register is equal to or smaller than 2.8 μm×2.8 μm.

With the method for manufacturing a solid-state image sensor according to the present invention, by carrying out the annealing, preferably a high-temperature short-time rapid heating annealing, after the ion implantation for forming the buried channel region constituting the shift register, it is possible to avoid forming crystal defects in a shift register and a photodetector portion, so that a high quality image signal with fewer white point defects and white vertical lines and less dark current compared with an image signal of the conventional solid-state image sensor can be obtained. In other words, even when crystal defects causing image defects are not supposed to be generated by carrying out the ion implantation for forming the photodetector portion and then the subsequent annealing or the subsequent high-temperature heat treatment also serving other purposes, if an annealing after the ion implantation for forming the shift register that is carried out before or after forming the photodetector portion is not appropriate, slips (sliding of crystals along a certain crystal orientation) or dislocations (aligning of crystal defects two-dimensionally or three-dimensionally) occur in the semiconductor substrate. As a result, crystal defects sometimes are generated not only in the shift register but also in the photodetector portion. The present invention prevents both the formation of the shift register including crystal defects and the formation of the semiconductor substrate including dislocations and slips, so that the photodetector portion can be made free from the influence of the generated crystal defects.

Also, with the method for manufacturing a solid-state image sensor according to the present invention, by carrying out the first ion implantation for forming the n-type buried channel region, the second ion implantation for forming the p-type region located under the buried channel region and the annealing, preferably a high-temperature short-time rapid heating annealing, after the first ion implantation and the second ion implantation, it is possible to prevent the formation of a shift register and a photodetector portion including crystal defects similarly to the above, so that a high quality image signal with fewer white point defects and white vertical lines and less dark current compared with an image signal of the conventional solid-state image sensor can be obtained. Moreover, it is possible to reduce the influence of impurity diffusion caused by the annealing and suppress a decrease in a saturation electric charge.

Further, with the method for manufacturing a solid-state image sensor according to the present invention, arsenic is used as the impurity for the ion implantation for forming the buried channel region or as the impurity for the first ion implantation for forming the n-type buried channel region in the case of forming the n-type buried channel region and the p-type region located under the buried channel region, thereby suppressing the amount of crystal defects to be generated in the shift register. Since arsenic has a larger atomic number than phosphorus, more point defects such as pairs of vacancy and interstitial atom are generated due to the ion implantation when using arsenic than when using phosphorus. However, arsenic is preferable because its atomic radius close to silicon makes it possible to reduce the generation of crystal defects causing image defects such as white point defects and white vertical lines compared with the case of using phosphorus by carrying out an appropriate annealing after the ion implantation.

Moreover, with the method for manufacturing a solid-state image sensor according to the present invention, the annealing temperature is set to be equal to or higher than the highest temperature of steps thereafter, making it possible to repair the crystal defects generated in the shift register sufficiently, thus reducing white vertical lines and dark current. In addition, this also is preferable because it is possible to reduce the influence of the diffusion of the ion-implanted impurity due to heat in the steps after the annealing, thereby suppressing a decrease in a saturation electric charge.

Also, with the method for manufacturing a solid-state image sensor according to the present invention, setting the annealing temperature to be equal to or higher than 950° C. is preferable because it becomes possible to repair crystal defects generated in the shift register sufficiently, thus reducing white vertical lines and dark current. Setting the annealing temperature to be equal to or lower than 1050° C. is preferable because it becomes possible to suppress the generation of slips and dislocations owing to the annealing, thereby preventing white point defects, white vertical lines and dark current from increasing.

Further, with the method for manufacturing a solid-state image sensor according to the present invention, setting the annealing period to be equal to or longer than 20 seconds is preferable because it becomes possible to repair crystal defects generated in the shift register sufficiently, thus reducing white vertical lines and dark current. Setting the annealing period to be equal to or shorter than 60 seconds is preferable because it becomes possible to suppress the generation of slips and dislocations owing to the annealing, thereby preventing white point defects, white vertical lines and dark current from increasing.

Additionally, with the method for manufacturing a solid-state image sensor according to the present invention, setting the heating rate of the annealing to be equal to or higher than 10° C./second is preferable because it becomes possible to repair crystal defects generated in the shift register sufficiently, thus reducing white vertical lines and dark current. Setting the heating rate of the annealing to be equal to or lower than 100° C./second is preferable because it becomes possible to suppress the generation of slips and dislocations owing to the annealing, thereby preventing white point defects, white vertical lines and dark current from increasing.

Moreover, with the above-noted method for manufacturing a solid-state image sensor according to the present invention, the annealing carried out in a nitrogen atmosphere is preferable because it becomes possible to repair the crystal defects generated in the shift register without generating any new crystal defects.

Furthermore, the method for manufacturing a solid-state image sensor according to the present invention is preferred when manufacturing a solid-state image sensor in which a surface area corresponding to a single pixel including a pair of the photodetector portion and the shift register is equal to or smaller than 2.8 μm×2.8 μm and more preferably is equal to or smaller than 2.4 μm×2.4 μm. When the concentration of impurities to be implanted (the dose of ion implantation) is increased for compensating for the reduction in the saturation electric charge (the maximum storage electric charge) caused by a decrease in the pixel area, the amount of point defects such as pairs of vacancy and interstitial atom generated at the time of ion implantation is likely to increase. However, the present invention is preferable because it is possible to provide a method for manufacturing a solid-state image sensor that prevents the generation of these crystal defects and can respond to increasingly finer pixels in a preferred manner.

### BRIEF DESCRIPTION OF THE DRAWINGS

FIG. 1 is a sectional view showing a solid-state image sensor in an embodiment of the present invention.

### DETAILED DESCRIPTION OF THE INVENTION

The following is a specific description of an embodiment of the present invention, with reference to the accompanying drawing.

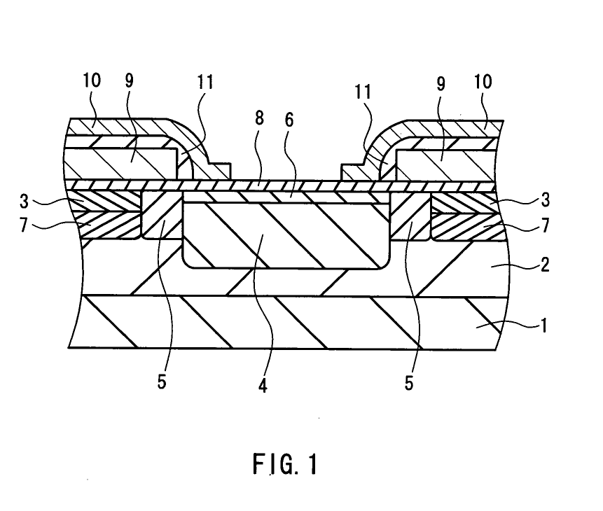

FIG. 1 is a sectional view showing a solid-state image sensor in an embodiment of the present invention. It is noted that this FIGURE only illustrates substantially a single pixel constituting the solid-state image sensor. A usual solid-state image sensor actually is constituted by a two-dimensional arrangement of plural pixels, each of which includes a photodetector portion and a shift register (a vertical transfer CCD portion) shown in FIG. 1.

The solid-state image sensor is formed as follows. A p-type well layer 2 is formed on an n-type silicon substrate 1. In the p-type well layer 2, an n-type buried channel region 3 and an n-type photodiode region 4 serving as a photodetector portion are formed in such a manner as to be separated by a p-type region 5. A surface of the photodetector portion in the upper portion of the n-type photodiode region 4 preferably is provided with a p-type high concentration region 6 for removing influences of an Si/SiO₂ interface (adverse effects of dark current and white point defects caused by an interface state or the like). Here, SiO₂ is an exemplary material of an insulating film 8. It is preferable that a p-type region 7 is formed under the n-type buried channel region 3. On the n-type buried channel region 3, a transfer gate electrode 9 made of polysilicon or the like is formed via the insulating film 8 of an SiO₂ film. A light-shielding film 10 that is made of tungsten or the like and has an opening region above the photodiode serving as the photodetector portion is formed on an upper surface of the transfer gate electrode 9. An interlayer insulating film 11 is formed between the transfer gate electrode 9 and the light-shielding film 10.

The n-type buried channel region 3 and the n-type photodiode region 4 serving as the photodetector portion in the above-described solid-state image sensor are formed by repeated formation and peeling of a photo resist and ion implantation. The transfer gate electrode 9, the light-shielding film 10 and the interlayer insulating film 11 also may be formed by known techniques.

Now, the following is a description of a characteristic of a method for manufacturing the solid-state image sensor according to the present embodiment.

The method for manufacturing the solid-state image sensor according to the present embodiment of the present invention includes carrying out an annealing after an ion implantation for forming the n-type buried channel region 3. In the present embodiment, it is preferable that the ion implantation for forming the n-type buried channel region 3 is carried out using arsenic. In the case of the solid-state image sensor shown in FIG. 1, a first ion implantation for forming the n-type buried channel region 3, a second ion implantation for forming the p-type region 7 to be located under the n-type buried channel region 3 and an annealing are conducted in this order. The annealing preferably is a high-temperature short-time rapid heating annealing in a nitrogen atmosphere. In this way, by conducting the annealing, preferably the high-temperature short-time rapid heating annealing, after the ion implantations, point defects such as pairs of vacancy and interstitial atom generated in the ion implantations can be removed before they are bound together to form stable crystal defects. Although there is no particular limitation, boron can be used for the second ion implantation, for example.

Here, it is preferable that the annealing temperature is 950° C. to 1050° C. The annealing temperature equal to or higher than 950° C. makes it possible to repair crystal defects generated in the shift register sufficiently, thus reducing white vertical lines and dark current. The annealing temperature equal to or lower than 1050° C. can suppress the generation of slips and dislocations owing to the annealing, thereby preventing white point defects, white vertical lines and dark current from increasing.

Further, it is preferable that the annealing period is 20 to 60 seconds. It also is preferable that an impurity used for the ion implantation for forming the buried channel region is arsenic. In order to suppress the diffusion of impurities owing to the annealing for activating the impurities, it is preferable that an annealing at a high temperature (950° C. to 1050° C.) for a short time (20 to 60 seconds) is carried out instead of an annealing at a relatively low temperature (800° C. to 900° C.) for a long time (10 minutes to several hours). In this way, the annealing period is shortened to suppress the diffusion of implanted impurities, and the annealing temperature is raised to compensate for an annealing effect reduced by the shortened annealing period.

The heating rate preferably is equal to or higher than 10° C./second. The reason is that, if a 600° C. to 700° C. temperature range is passed at less than 10° C./second, it is likely that primary defects generated by the ion implantation are bound together to form defect clusters. Such defect clusters grow to form secondary defects, which are difficult to repair even by heating at a temperature higher than 700° C. On the other hand, the heating rate preferably is equal to or lower than 100° C./second because the heating rate higher than 100° C./second may generate a slip in a wafer in an annealing furnace.

Moreover, it is preferable that the annealing atmosphere is a nitrogen atmosphere. The reason is that the annealing in a nitrogen atmosphere makes it possible to repair the crystal defects generated in the shift register without generating any new crystal defects.

When an output screen in an imaging apparatus is examined for white point defects and white vertical lines, white point defects and white vertical lines are generated in the output screen of the imaging apparatus using a conventional solid-state image sensor produced by an ion implantation for forming a shift register followed by no annealing. On the other hand, no white point defects or white vertical lines are found, or an extremely small number of them is found in the imaging apparatus using the solid-state image sensor according to the present embodiment.

Furthermore, the dark current generated in the solid-state image sensor according to the present embodiment can be made much smaller than that generated in the conventional solid-state image sensor produced by the ion implantation for forming the shift register followed by no annealing.

Consequently, the method for manufacturing a solid-state image sensor according to an embodiment of the present invention makes it possible to prevent the formation of a shift register and a photodetector portion that include crystal defects, thereby improving yield.

Although the solid-state image sensor is formed using the n-type silicon substrate 1 in the above-described example, it also can be formed using a p-type silicon substrate in a similar manner. At this time, the p-type well layer 2 shown in FIG. 1 does not have to be formed in the semiconductor substrate, and the p-type silicon substrate can be used as it is.

Since the object of the present invention is to reduce the generation of image defects caused by crystal defects in the shift register, the present invention focuses on this specific point, and the description thereof has been directed to the method for manufacturing a solid-state image sensor in which the crystal defects in the shift register are reduced. Therefore, the annealing after the ion implantation for forming the photodetector portion is not particularly limited in the present invention. The annealing after the ion implantation for the photodetector portion may be employed suitably but is not always necessary. For example, in the case of reducing the dose of ion implantation or conducting a heat treatment after the ion implantation for the photodetector portion (a high-temperature heat treatment that does not aim at an additional annealing specifically for repairing crystal defects, e.g., a surface flattening treatment afterwards), the annealing after the ion implantation for the photodetector portion can be omitted. Even in the case of performing the annealing after the ion implantation for the photodetector portion, the order of the annealing after the ion implantation for the photodetector portion and the annealing after the ion implantation for the shift register may be determined suitably as necessary depending on the production process to be employed. Also, the annealing suitably may be carried out after each of the ion implantation for the photodetector portion and that for the shift register, or be carried out at one time after both of these ion implantations are finished or only after the ion implantation for the shift register as described above, as necessary depending on the production process to be employed. The embodiment described above and an example described below employ the ion implantation for the photodetector portion, the annealing of the photodetector portion (furnace annealing), the ion implantation for the shift register and the annealing of the shift register (RTA: rapid thermal annealing) in this order.

Hereinafter, in order to facilitate the understanding of the present invention, the present invention will be described further by way of an example. However, it should be noted that the present invention is by no means limited by the modes described in this example.

### EXAMPLE 1

The following is a specific description of an example of the present invention, with reference to FIG. 1.

FIG. 1 is a sectional view showing a solid-state image sensor in an example of the present invention. As mentioned earlier, it is noted that this FIGURE only illustrates substantially a single pixel constituting the solid-state image sensor. A usual solid-state image sensor actually is constituted by a two-dimensional arrangement of plural pixels, each of which includes a photodetector portion and a shift register (a vertical CCD portion) shown in FIG. 1.

The solid-state image sensor was produced as follows. A p-type well 2 was formed on an n-type silicon substrate 1 by a high-energy boron ion implantation (1800 keV, 1.5×10¹¹ cm⁻²). In the p-type well 2, an n-type photodiode region 4 serving as a photodetector portion was formed by an arsenic ion implantation (550 keV, 2.6×10¹² cm⁻²), followed by annealing in a nitrogen atmosphere (1000° C., 20 minutes). Thereafter, an n-type buried channel region 3 was formed by an arsenic ion implantation (110 keV, 5.8×10¹² cm⁻²), and a p-type region 7 to be located under the buried channel region was formed by a boron ion implantation (180 keV, 8×10¹¹ cm⁻²), followed by annealing in a nitrogen atmosphere (1000° C., 40 seconds, a heating/cooling rate of 50° C./second). Next, an insulating film 8 formed of a silicon oxide film (thickness: 30 nm) was formed by thermal oxidation (900° C.). A p-type region 5 was formed by a boron ion implantation (40 keV, 7×10¹² cm⁻²) in such a manner as to separate the n-type buried channel region 3 and the n-type photodiode region 4.

Then, a polysilicon film (thickness: 250 nm) was grown by a CVD method (chemical vapor deposition: 530° C.), and formed into a transfer gate electrode 9 by dry etching. Thereafter, the transfer gate electrode 9 was covered with a silicon oxide film by thermal oxidation (900° C.). This silicon oxide film corresponds to a part of an interlayer insulating film 11, which will be described later. A surface of the photodetector portion in the upper portion of the n-type photodiode region 4 was provided with a p-type high concentration region 6 for removing influences of an Si/SiO₂ interface state by a boron ion implantation (10 keV, 5×10¹³ cm⁻²). Subsequently, the interlayer insulating film 11 made of SiO₂ (thickness: 60 nm) was formed by a CVD method (680° C.), a light-shielding film 10 (thickness: 200 nm) made of tungsten was formed by sputtering, and an opening region was formed above the photodetector portion by dry etching, thereby obtaining a solid-state image sensor. The surface area corresponding to a single pixel including a pair of the photodetector portion and the shift register was 2.4 μm×2.4 μm.

In an output screen of the thus obtained solid-state image sensor in the present example, white point defects, white vertical lines and dark current were examined. White point defects were found in 5 pixels out of 3,000,000 pixels and 2 white vertical lines were generated in an output screen of an imaging apparatus using a conventional solid-state image sensor produced by the ion implantation for forming the shift register followed by no annealing. On the other hand, no white point defects or white vertical lines were found in an imaging apparatus using the solid-state image sensor in the present example.

Further, when the dark current generated in the solid-state image sensor of the present example was measured, it was 0.5 mV under a temperature condition of 60° C. On the other hand, the dark current generated in the case of the conventional solid-state image sensor produced by the ion implantation for forming the shift register followed by no annealing was 1 mV when measured while keeping the other conditions being the same. This confirmed that the dark current could be reduced substantially by half by the method for manufacturing a solid-state image sensor in the present example.

Consequently, the method for manufacturing a solid-state image sensor according to the present invention makes it possible to prevent the formation of a shift register and a photodetector portion that include crystal defects, thereby improving yield.

Although the solid-state image sensor was formed using the n-type silicon substrate 1 in the above-described example, it also can be formed using a p-type silicon substrate in a similar manner. At this time, the p-type well layer 2 shown in FIG. 1 does not have to be formed in the substrate, and the p-type silicon substrate can be used as it is.

The present invention provides a method for manufacturing a solid-state image sensor that prevents the formation of a shift register and a photodetector portion including crystal defects, achieves an excellent output image quality and a large saturation electric charge and is useful for a videotape camera-recorder, a digital still camera or the like.

The invention may be embodied in other forms without departing from the spirit or essential characteristics thereof. The embodiments disclosed in this application are to be considered in all respects as illustrative and not limiting. The scope of the invention is indicated by the appended claims rather than by the foregoing description, and all changes which come within the meaning and range of equivalency of the claims are intended to be embraced therein.

What is claimed is:

1. A method for manufacturing a solid-state image sensor, comprising:
forming a photodetector portion for a photoelectric conversion in a semiconductor substrate; and
forming a shift register for transferring a signal charge read out from the photodetector portion;
wherein the forming of the shift register comprises an annealing after an ion implantation for forming a buried channel region constituting the shift register.

2. The method according to claim 1, wherein the shift register comprises an n-type buried channel region and a p-type region located under the buried channel region,
the ion implantation for forming the shift register comprises a first ion implantation for forming the n-type buried channel region and a second ion implantation for forming the p-type region located under the buried channel region, and
the annealing is carried out after the first ion implantation and the second ion implantation.

3. The method according to claim 1, wherein an impurity used for the ion implantation is arsenic.

4. The method according to claim 2, wherein an impurity used for the first ion implantation is arsenic.

5. The method according to claim 1, wherein a temperature of the annealing is set to be equal to or higher than a highest temperature of steps thereafter.

6. The method according to claim 2, wherein a temperature of the annealing is set to be equal to or higher than a highest temperature of steps thereafter.

7. The method according to claim 1, wherein a temperature of the annealing is 950° C. to 1050° C.

8. The method according to claim 2, wherein a temperature of the annealing is 950° C. to 1050° C.

9. The method according to claim 5, wherein a period for the annealing is 20 to 60 seconds.

10. The method according to claim 6, wherein a period for the annealing is 20 to 60 seconds.

11. The method according to claim 5, wherein a heating rate of the annealing is 10° C./second to 100° C./second.

12. The method according to claim 6, wherein a heating rate of the annealing is 10° C./second to 100° C./second.

13. The method according to claim 1, wherein the annealing is carried out in a nitrogen atmosphere.

14. The method according to claim 2, wherein the annealing is carried out in a nitrogen atmosphere.

15. The method according to claim 1, wherein a surface area corresponding to a single pixel including a pair of the photodetector portion and the shift register is equal to or smaller than 2.8 μm×2.8 μm.

16. The method according to claim 2, wherein a surface area corresponding to a single pixel including a pair of the photodetector portion and the shift register is equal to or smaller than 2.8 μm×2.8 μm.
